(19) United States
(12) Patent Application Publication
(10) Pub. No.: US 2025/0025982 A1
(43) Pub. Date: Jan. 23, 2025

(54) CHEMICAL MECHANICAL POLISHING (CMP) APPARATUS

(71) Applicant: Samsung Electronics Co., Ltd., Suwon-si (KR)

(72) Inventors: DONGHOON KWON, Suwon-si (KR); BOUN YOON, Suwon-si (KR)

(21) Appl. No.: 18/427,486

(22) Filed: Jan. 30, 2024

(30) Foreign Application Priority Data
Jul. 19, 2023 (KR) 10-2023-0094171

(51) Int. Cl. B24B 37/04; B24B 37/27; B24B 53/017; B24B 57/02

(52) U.S. Cl. CPC B24B 37/04; B24B 37/27; B24B 53/017; B24B 57/02

(57) ABSTRACT

A chemical mechanical polishing apparatus including a substrate support plate configured to support a substrate, a rotation member positioned on the substrate support plate and configured to include a polishing pad for polishing the substrate, and a jig member positioned on the substrate support plate and movably connected to the rotation member.

### CROSS-REFERENCE TO RELATED APPLICATION

This application claims priority to and the benefit of Korean Patent Application No. 10-2023-0094171, filed in the Korean Intellectual Property Office on Jul. 19, 2023, the entire contents of which are incorporated herein by reference.

### BACKGROUND

### Technical Field

A technical idea of the present disclosure relates to a chemical mechanical polishing (CMP) apparatus, and more specifically, to a chemical mechanical polishing apparatus that precisely controls polishing distribution on a substrate.

### Description of the Related Art

A chemical mechanical polishing (CMP) apparatus is used in a polishing process to planarize a surface of a semiconductor wafer. In general, semiconductor devices are manufactured by selectively or repeatedly performing processes such as photolithography, etching, diffusion, chemical vapor deposition, ion implantation, or metal deposition on a wafer. In this process, the semiconductor wafer undergoes a chemical mechanical polishing (CMP) process such as etch back during planarization to facilitate the formation of a circuit pattern on the surface.

For the CMP process, a polishing device is generally used, in which a head portion with a wafer mounted on a polishing pad positioned on a platen is pressed to polish the wafer on the polishing pad.

However, the chemical mechanical polishing apparatus used in a general CMP process has a problem in that averaging out occurs, in which polishing distribution on the substrate deviates from an average value, making it difficult to precisely control the distribution.

### SUMMARY

The technical object that the present disclosure provides is a chemical mechanical polishing apparatus capable of precisely controlling polishing distribution on a substrate.

An embodiment of the present disclosure provides a chemical mechanical polishing apparatus including a substrate support plate configured to support a substrate, a rotation member positioned on the substrate support plate and configured to include a polishing pad for polishing the substrate, and a jig member positioned on the substrate support plate and movably connected to the rotation member.

Another embodiment of the present disclosure provides a chemical mechanical polishing apparatus including a substrate support plate configured to support a substrate, a rotation member positioned on the substrate support plate and configured to include a polishing pad for polishing the substrate, and a jig member positioned on the substrate support plate and movably connected to the rotation member, wherein the rotation member includes a slurry supplier positioned on the polishing pad and configured to include a slurry supply valve positioned to surround the polishing pad, and the slurry supply valve includes at least one nozzle for directly supplying slurry onto the substrate.

Another embodiment of the present disclosure provides a chemical mechanical polishing apparatus including a substrate support plate configured to adsorb and fix the substrate by providing pressure to the substrate, a rotation member configured to include a polishing pad positioned on the substrate support plate to polish the substrate, a polishing pad support plate positioned on the polishing pad to support the polishing pad, a polishing pad driver configured to rotate the polishing pad and the polishing pad support plate, and a slurry supplier positioned to extend through the polishing pad, and a jig member configured to include a first jig member positioned on the substrate support plate to support and move the rotation member and a second jig member configured to support the first jig member.

### BRIEF DESCRIPTION OF THE DRAWINGS

FIG. 1A illustrates a perspective view of a chemical mechanical polishing apparatus according to an embodiment of the present disclosure.

FIG. 1B illustrates a top plan view of the chemical mechanical polishing apparatus of FIG. 1A.

FIG. 1C illustrates a cross-sectional view taken along an AA′ direction of the chemical mechanical polishing apparatus of FIG. 1B.

FIGS. 2A to 2D schematically illustrate a method of driving a chemical mechanical polishing apparatus according to an embodiment of the present disclosure.

FIG. 3A and FIG. 3B illustrate enlarged views of a region M in FIG. 1C.

FIG. 4A and FIG. 4B illustrate enlarged views of a region B of FIG. 2B and illustrate various examples of a slurry supplier.

FIGS. 5A to 5D illustrate various examples of a nozzle positioned on a polishing pad of the present disclosure.

FIG. 6A illustrates a perspective view of a chemical mechanical polishing apparatus according to an embodiment of the present disclosure.

FIG. 6B illustrates a cross-sectional view taken along a CC′ direction of the chemical mechanical polishing apparatus of FIG. 6A.

FIG. 6C illustrates a plan view of the chemical mechanical polishing apparatus of FIG. 6A.

FIGS. 7A to 7C schematically illustrate a method of driving a chemical mechanical polishing apparatus according to another embodiment of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

The present disclosure will be described more fully hereinafter, in which embodiments of the disclosure are shown. As those skilled in the art would realize, the described embodiments may be modified in various different ways, all without departing from the spirit or scope of the present disclosure.

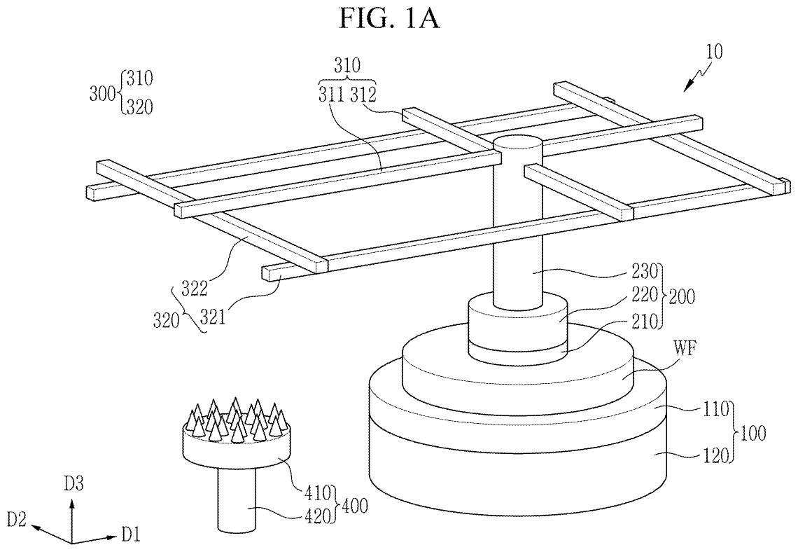

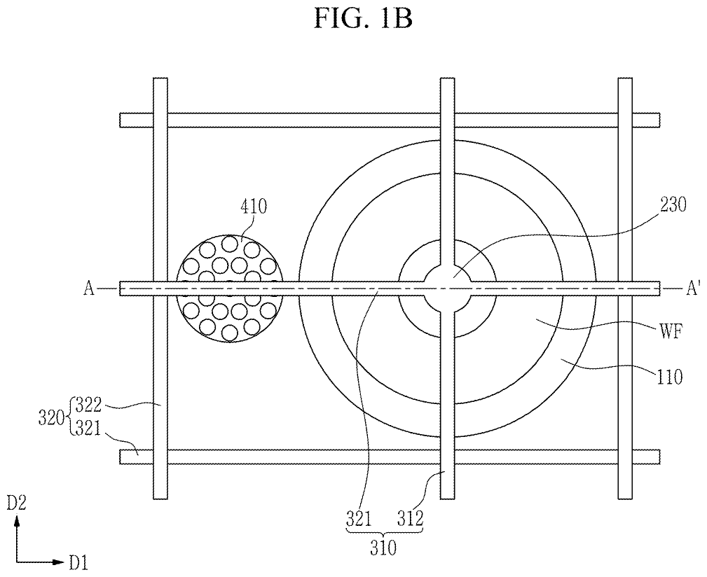

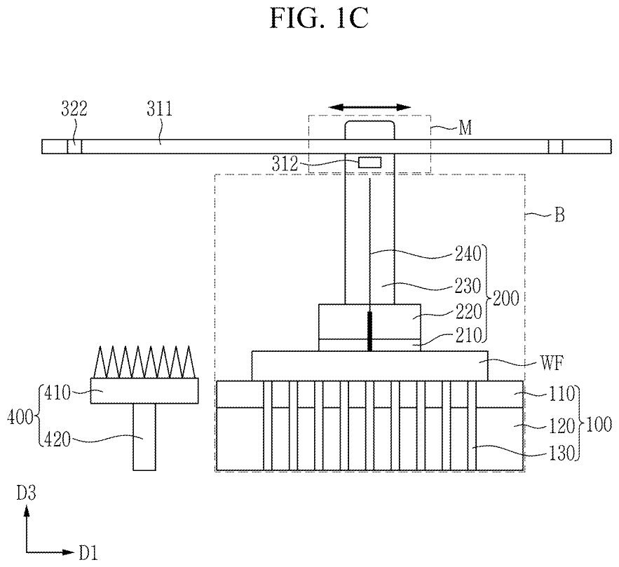

FIG. 1A illustrates a perspective view of a chemical mechanical polishing apparatus 10 according to an embodiment of the present disclosure, FIG. 1B illustrates a top plan view of the chemical mechanical polishing apparatus 10 of FIG. 1A, and FIG. 1C illustrates a cross-sectional view taken along an AA′ direction of the chemical mechanical polishing apparatus 10 of FIG. 1B.

Referring to FIGS. 1A to 1C, the chemical mechanical polishing apparatus 10 according to an embodiment of the present disclosure may include a substrate support plate 100, a rotation member 200, and a jig member 300. In the chemical mechanical polishing apparatus 10, a substrate WF supported on the substrate support plate 100 is polished by the rotation member 200 precisely moved by the jig member 300, enabling more precise polishing control.

The substrate support plate 100 may be a member positioned below the substrate (e.g., wafer) WF to support the substrate WF to be polished. The substrate support plate 100 may physically fix the substrate WF, and may apply pressure to the substrate WF to adsorb and fix the substrate. For example, the substrate support plate 100 may apply pressure, such as air, to the substrate WF to adsorb (e.g., fix) the substrate WF and support the substrate WF. In an embodiment, the substrate support plate 100 may include a first support plate 110 supporting the substrate WF and a second support plate 120 positioned below the first support plate 110. The first support plate 110 may be attached to the substrate WF, and may serve to control external force depending on zones of the substrate WF. For example, the substrate WF may be attached to a first surface of the first support plate 110.

For example, the first support plate 110 may be a membrane, and may include a flexible material. Specifically, the membrane may be a member that assists in applying independently controllable pressure to relevant zones on the substrate WF by a plurality of independently controllable pressure chambers.

The second support plate 120 may be positioned below the first support plate 110 to rotate the substrate support plate 100. Specifically, the second support plate 120 may be a member that applies rotational energy so that the substrate support plate 100 supporting the substrate WF is rotatable in a certain direction.

In an embodiment, the substrate support plate 100 may include a pressure provider 130 positioned through the first support plate 110 and the second support plate 120. Specifically, the pressure provider 130 may include a hole extending through the first support plate 110 and the second support plate 120, and may adsorb the substrate WF by controlling the pressure of a gas provided together with air through the hole.

Specifically, the substrate WF may be adsorbed and fixed to the first support plate 110 by a gas provided from the pressure provider 130, and as the first support plate 110 rotates by the second support plate 120, the substrate WF may rotate in the same rotation direction and speed as those of the substrate support plate 100. For example, the second support plate 120 may support the first support plate 110 using a chuck member and may also rotate the substrate support plate 100. The second support plate 120 may contact a second surface of the first support plate 110. The first surface of the first support plate 110 may be opposite to the second surface of the first support plate 110. A first surface of the substrate WF may contact the first surface of the first support plate 110.

The rotation member 200 may be a member that is positioned on the substrate support plate 100, and polishes the substrate WF. For example, the rotation member 200 may polish a second surface of the substrate WF. The second surface of the substrate WF may be opposite to the first surface of the substrate WF. In an embodiment, the rotation member 200 may include a polishing pad 210, a polishing pad support plate 220 positioned on the polishing pad 210, and a polishing pad driver 230 that rotates the polishing pad 210 and the polishing pad support plate 220.

The polishing pad 210 may uniformly planarize a surface (e.g., the second surface) of the substrate WF, and may be a member that performs mechanical polishing on the substrate WF. The polishing pad 210 may be provided as a circular plate, but the present disclosure is not limited thereto.

In an embodiment, the polishing pad 210 may include a polishing surface having a predetermined roughness. While a chemical mechanical polishing process is performed, the polishing surface of the polishing pad 210 may be in contact with the substrate WF (e.g., the second surface of the substrate WF) to mechanically polish the substrate WF. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The polishing pad 210 may include a porous material having a plurality of micropores. The pores (e.g., micropores) of the polishing pad 210 may be a member that accommodates slurry provided during the chemical mechanical polishing process and assists not only in mechanically polishing the substrate WF but also in chemically polishing the substrate WF. The polishing pad 210 may include a polyurethane pad as a non-limiting example.

In an embodiment, a diameter of the polishing pad 210 may be smaller than a diameter of the substrate WF. Since the diameter of the polishing pad 210 is smaller than the diameter of the substrate WF, there is an advantage in that it is easy to polish a local region of the substrate WF.

The polishing pad support plate 220 may be a member that supports the polishing pad 210. Specifically, the polishing pad support plate 220 may be positioned on the polishing pad 210, and may be a member that is removable from the polishing pad 210, which is a consumable item, or may be a member that fixes the polishing pad 210.

The polishing pad driver 230 may be a member that fixes and rotates the polishing pad 210 and the polishing pad support plate 220. Specifically, the polishing pad driver 230 may drive the polishing pad 210 to press the substrate WF in a direction (−D3) opposite to a direction D3 by a predetermined range. The polishing pad driver 230 may rotate the polishing pad 210 and the polishing pad support plate 220 in the same direction as a rotation direction of the substrate WF.

In an embodiment, the polishing pad driver 230 may be rotated by a member such as a motor. The polishing pad driver 230 may have a driving member such as a motor built into the polishing pad driver 230 to rotate the rotation member 200, and a separate external driving member may be connected to the polishing pad driver 230 to enable the polishing pad driver 230 to rotate by the driving member.

In an embodiment, the polishing pad driver 230 may be configured as a rotary union. The rotary union, which is a member capable of fluid connection, may include a shaft or be configured in a hollow form. The rotary union may easily supply slurry directly to the substrate WF by a slurry supplier 240 built into the rotation member 200.

In an embodiment, the rotation member 200 may include the slurry supplier 240 that supplies slurry. The slurry supplier 240 may be a member that supplies slurry to the substrate WF, allowing the substrate WF to undergo chemical polishing through a chemical reaction with the slurry.

In an embodiment, the slurry supplier 240 may be positioned within the rotation member 200. Specifically, the slurry supplier 240 may be installed and positioned in the rotation member 200. More specifically, the slurry supplier 240 may be positioned to extend through at least a portion of the polishing pad driver 230, the polishing pad support plate 220, and the polishing pad 210. The slurry supplier 240 may be built into the rotation member 200, and may directly supply slurry to a portion of the substrate WF that is subject to polishing if the polishing pad 210 performs polishing of the substrate WF.

In an embodiment, the substrate support plate 100 may rotate in the same direction as that of the rotation member 200. For example, the substrate support plate 100 and the rotation member 200 may rotate in the same direction, clockwise or counterclockwise. Since the substrate support plate 100 and the rotation member 200 rotate in the same direction and at different speeds, the substrate WF may be polished precisely.

The jig member 300 may be positioned above the substrate support plate 100. The jig member 300 may be a member that supports the rotation member 200 and is movably connected thereto. Specifically, the jig member 300 may support the rotation member 200, and may move the rotation member 200 to a target polishing portion of the substrate WF.

In an embodiment, the jig member 300 may be a member that guides the rotation member 200 to move in a direction parallel to the substrate WF (e.g., a surface of the substrate WF). Specifically, the jig member 300 may be a member that assists movement of the rotation member 200 when the rotation member 200 is moved by a moving member such as a motor.

For example, if a central portion of the substrate WF is a target to be polished, the jig member 300 may support the rotation member 200 and assist the movement of the rotation member 200 when the rotation member 200 moves to the central portion of the substrate WF. The jig member 300 may assist the polishing pad 210 of the rotation member 200 to be positioned on the central portion of the substrate WF.

If an edge portion of the substrate WF is a target to be polished, when the rotation member 200 moves to the edge portion of the substrate WF, the jig member 300 may support the rotation member 200 and assist the movement of the rotation member 200. The jig member 300 may assist the polishing pad 210 of the rotation member 200 to be positioned on the edge portion of the substrate WF.

As such, the jig member 300 may assist in precisely moving the rotation member 200 including the polishing pad 210 to facilitate distribution control of the substrate WF. The jig member 300 may assist the rotation member 200 in moving in a first direction and a second direction horizontally intersecting the first direction. Specifically, the jig member 300 may precisely control a polishing portion of the substrate WF by moving the rotation member 200 in the first direction, which is a direction D1, and the second direction, which is a direction D2, which intersects the direction D1 horizontally. The third direction D3 intersects both the first direction D1 and the second direction D2.

In an embodiment, the jig member 300 may include a first jig member 310 that supports and moves the rotation member 200 and a second jig member 320 that supports the first jig member 310. The first jig member 310 may support the rotation member 200, e.g., the polishing pad driver 230 of the rotation member 200.

The first jig member 310 supports the rotation member 200, and may include a first movement jig 311 extending in the first direction and a second movement jig 312 extending in the second direction. The first movement jig 311 may extend in the first direction, which is the direction D1 to move the rotation member 200 in the first direction. The second movement jig 312 may extend in the second direction, which is the direction D2 to move the rotation member 200 in the second direction.

The first movement jig 311 and the second movement jig 312 may move the rotation member 200 together, and the rotation member 200 may perform two-dimensional movement on a plane formed by the direction D1 and the direction D2. As such, the rotation member 200 may be moved by the first jig member 310 including the first movement jig 311 and the second movement jig 312 to precisely control the polishing portion of the substrate WF. The second jig member 320 may include a first support jig 321 extending in the first direction and supporting the second movement jig 312, and a second support jig 322 extending in the second direction and supporting the first movement jig 311. More specifically, the first support jig 321 may extend in the first direction, which is the direction D1, and the second support jig 322 may extend in the second direction, which is the direction D2.

The first support jig 321 may be a member that supports the second movement jig 312 when the second movement jig 312 moves in the direction D2 or in a direction −D2 opposite to the direction D2. Specifically, the first support jig 321 may be formed to include a pair of members to support opposite end areas of the second movement jig 312.

The second support jig 322 may be a member that supports the first movement jig 311 when the first movement jig 311 moves in the direction D1 or in a direction −D1 opposite to the direction D1. Specifically, the second support jig 322 may be formed to include a pair of members to support opposite end areas of the first movement jig 311.

In an embodiment, the chemical mechanical polishing apparatus 10 may include a conditioner 400. In an embodiment, the conditioner 400 may be positioned to be spaced apart from the substrate support plate 100. For example, the conditioner 400 may be positioned at a predetermined distance from the substrate support plate 100 in the first direction, which is the direction D1.

In an embodiment, the conditioner 400 may be positioned below the jig member 300. Specifically, the conditioner 400 may be positioned to be spaced apart from the substrate support plate 100 in the first direction, which is the direction D1, and to be spaced apart from the jig member 300 in the third direction, which is the direction D3.

In an embodiment, the conditioner 400 may polish a surface of the polishing pad 210. The polishing pad 210 may be moved over the conditioner 400 by the jig member 300. Thereafter, the moved polishing pad 210 may be positioned in contact with a polishing surface 410, and the polishing surface 410 and the polishing pad 210 are rotated together to polish the polishing pad 210. In this case, the conditioner 400 may move vertically in contact with the polishing pad 210 to perform polishing.

In an embodiment, the conditioner 400 may maintain the surface roughness of the polishing pad 210 in an optimal state. Specifically, the conditioner 400 may include the polishing surface 410 for controlling the surface roughness of the polishing pad 210. The polishing surface 410 may be formed by attaching polishing particles, such as artificial diamond particles, to a circular disk made of a metal through a metal adhesive layer formed of, e.g., nickel (Ni).

In an embodiment, the conditioner 400 may include a conditioner driver 420 that rotates the polishing surface 410. The conditioner driver 420 may be positioned below the polishing surface 410 and may rotate the conditioner 400 to polish the polishing pad 210.

Accordingly, the conditioner 400 may stably maintain roughness of the polishing pad 210 to ensure that the substrate WF is effectively polished while the chemical mechanical polishing apparatus performs the polishing process.

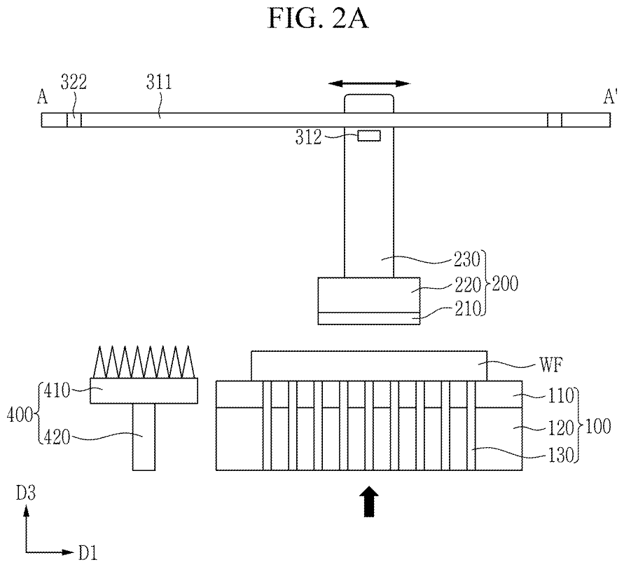

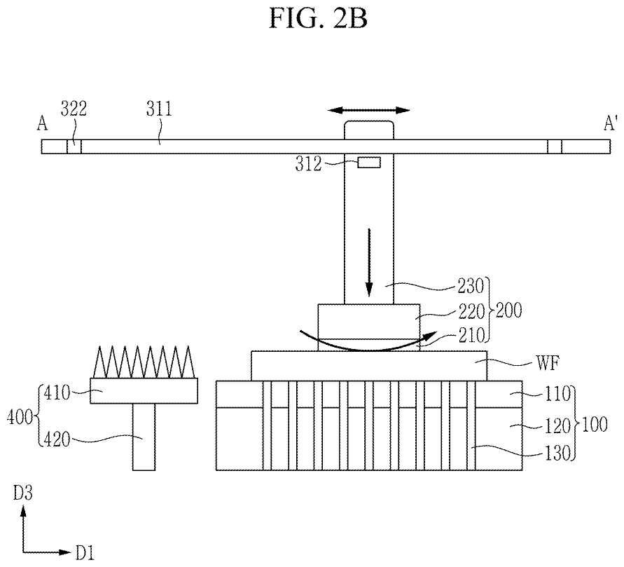

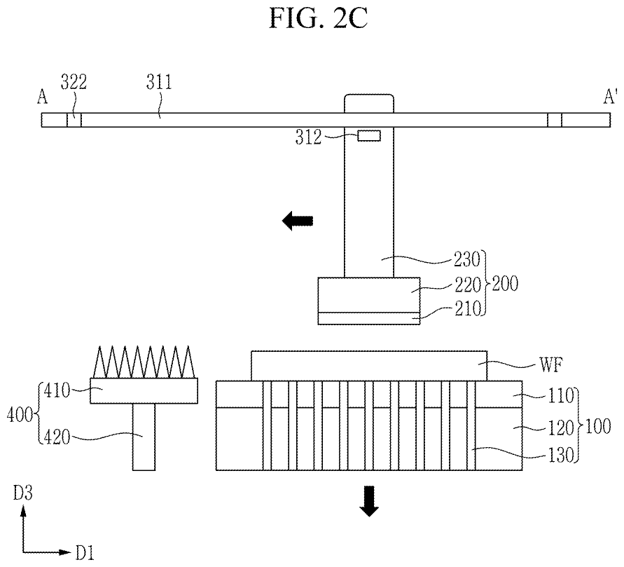

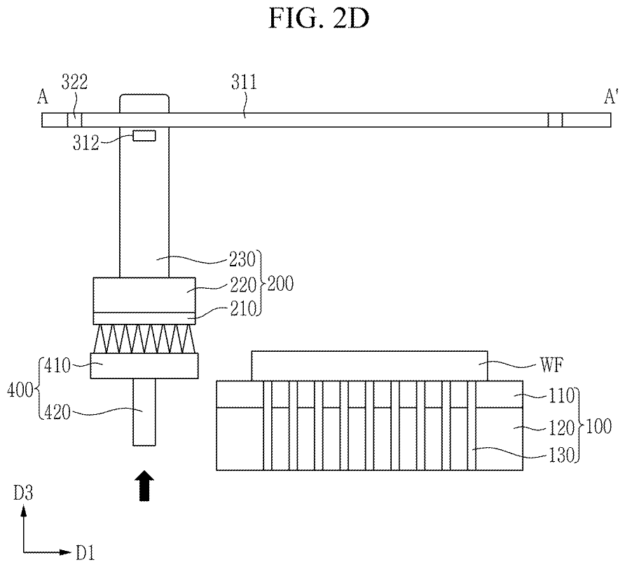

FIGS. 2A to 2C schematically illustrate a method of driving a chemical mechanical polishing apparatus 10 according to an embodiment of the present disclosure.

Referring to FIG. 2A, the rotation member 200 is positioned on the substrate support plate 100 on which the substrate WF is fixed, and moves over the area of the substrate WF that is the target to be polished. Specifically, the rotation member 200 is precisely moved to an area of the substrate WF that is the target to be polished by the first jig member 310 including the first movement jig 311 and the second movement jig 312 in the jig member 300.

In an embodiment, the substrate support plate 100 may move in a direction that is perpendicular to the substrate WF. Specifically, if the rotation member 200 including the polishing pad 210 is placed on the substrate WF by the first jig portion 310, the substrate support plate 100 that fixes the substrate WF moves in the third direction, which is the direction D3, so that the polishing pad 210 and the substrate WF are positioned to be in contact with each other. In an embodiment, while the substrate support plate 100 and the rotation member 200 may rotate in the same direction, polishing of the substrate WF may be performed.

In FIG. 2A, polishing the central portion of the substrate WF is illustrated, but this is a non-limiting example, and the distribution of the substrate WF may be controlled by locally polishing various areas of the substrate WF, such as an edge portion of the substrate WF or an intermediate region between the central portion and the edge portion.

Referring to FIG. 2B, when the substrate WF is polished, the rotation member 200 may be pressed against the substrate WF in a direction that is opposite to the third direction. Specifically, the rotation member 200 may be pressed against the substrate WF in a direction opposite to the third direction, which is the direction −D3, which is opposite to the direction D3, and polishing of the substrate WF may be performed more precisely. As such, as the substrate support plate 100 as well as the rotation member 200 moves in the third direction or in a direction opposite to the third direction, polishing of the substrate WF may be performed more precisely by controlling a polishing degree.

Referring to FIG. 2C, after polishing of the substrate WF is performed for a predetermined period of time, the substrate support plate 100 may move in the direction −D3 opposite to the direction D3, which is opposite to the third direction to be spaced apart from the rotation member 200.

In an embodiment, after polishing of the substrate WF is performed for a predetermined period of time, the rotation member 200 including the polishing pad 210 is moved to the conditioner 400 to adjust the surface roughness of the polishing pad 210. In this case, the rotation member 200 is moved and positioned on the conditioner 400 by the first jig member 310.

Referring to FIG. 2D, when the rotation member 200 is positioned on the conditioner 400, the conditioner 400 may move in the third direction to perform polishing to control the surface roughness of the polishing pad 210 of the rotation member 200. Specifically, the surface roughness of the polishing pad 210 may be controlled as the polishing surface 410 on which diamond particles are positioned rotates.

A process of controlling the surface roughness of the polishing pad 210 is a non-limiting example, the conditioner 400 may rotate to control the surface roughness of the polishing pad 210, and the conditioner 400 and the rotation member 200 may rotate together to control the surface roughness of the polishing pad 210.

In an embodiment, a diameter of the polishing surface 410 may be larger than a diameter of the polishing pad 210. Since the diameter of the polishing surface 410 is greater than the diameter of the polishing pad 210, an entire area of the polishing pad 210 may be controlled to have uniform illuminance. If the diameter of the polishing surface 410 is smaller than the diameter of the polishing pad 210, there is a problem in that the roughness of the polishing pad 210 is controlled unevenly.

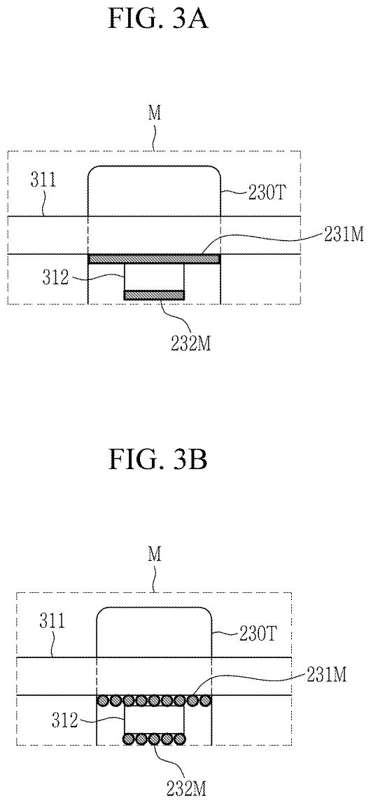

FIG. 3A and FIG. 3B illustrate enlarged views of a region M in FIG. 1C.

Referring to FIGS. 3A to 3C, the rotation member 200 may be moved by the first movement jig 311 and the second movement jig 312. Referring again to FIG. 3A, the polishing pad driver 230 in the rotation member 200 includes an upper polishing pad driver 230T, and may include a first auxiliary mover 231M and a second auxiliary mover 232M that assist movement of the first movement jig 311 and the second movement jig 312 in the upper polishing pad driver 230T. The first movement jig 311 may pass through a first opening disposed in the upper polishing pad driver 230T. The second movement jig 312 may pass through a second opening disposed in the upper polishing pad driver 230T. The first opening and the second opening may be disposed at different levels with respect to the third direction D3. For example, the first opening may be disposed at a level higher than the second opening. The first movement jig 311 may pass completely through the upper polishing pad driver 230T via the first opening. The second movement jig 312 may pass completely through the upper polishing pad driver 230T via the second opening.

The first auxiliary mover 231M and the second auxiliary mover 232M may be positioned below the first movement jig 311 and the second movement jig 312, respectively, and the rotation member 200 may move along the first movement jig 311 in a first direction and the second movement jig 312 in a second direction that intersects (e.g., perpendicular to) the first direction.

In an embodiment, the first auxiliary mover 231M and the second auxiliary mover 232M may each include a sliding member. For example, the first auxiliary mover 231M and the second auxiliary mover 232M may move the rotation member 200 by sliding the first movement jig 311 and the second movement jig 312, respectively. In an embodiment, the first auxiliary mover 231M and the second auxiliary mover 232M may be separately driven by external power. In this case, since the first auxiliary mover 231M and the second auxiliary mover 232M include a sliding member, the rotation member 200 may be easily moved to a target portion to be polished.

Referring again to FIG. 3B, in an embodiment, the first auxiliary mover 231M and the second auxiliary mover 232M may be configured to include roller members. For example, the roller member may be configured to include a member such as a round rotating plate or a conveyor belt. If the roller member is a member such as a round rotating plate, a plurality of rotating plates are positioned on the first auxiliary mover 231M and the second auxiliary mover 232M, the rotation member 200 may be moved by the first moving jig 311 and the second moving jig 312. In this case, since the first auxiliary mover 231M and the second auxiliary mover 232M are configured to include the roller members, the movement of the rotation member 200 may be easily assisted.

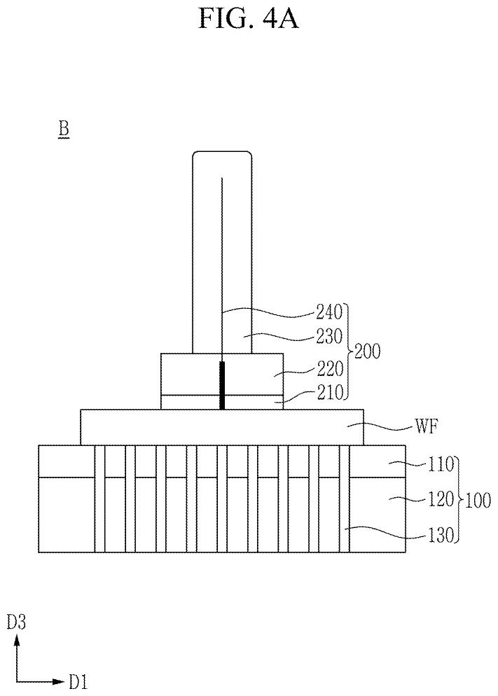

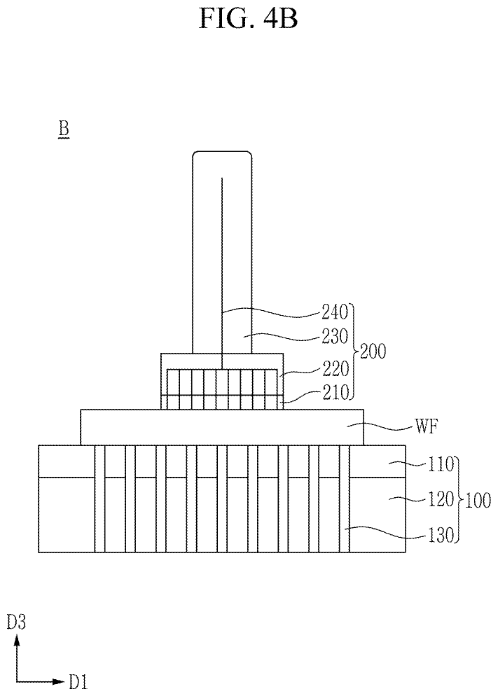

FIG. 4A and FIG. 4B illustrate enlarged views of a region B of FIG. 2B and illustrate various examples of a slurry supplier 240.

Referring to FIG. 4A, in an embodiment, the slurry supplier 240 is embedded in the rotation member 200 and may be positioned through the polishing pad 210. The slurry supplier 240 may be positioned to extend through at least a portion of the polishing pad driver 230 of the rotation member 200, the polishing pad support plate 220, and the polishing pad 210 to supply slurry to the substrate WF while the rotation member 200 rotates.

In an embodiment, the slurry supplier 240 may be positioned through a central portion of the polishing pad 210. As the slurry is supplied to the substrate WF from the central portion of the polishing pad 210 and the support plate 100 and the rotation member 200 rotate, economic efficiency may be improved by reducing a usage amount of slurry, and the slurry may be evenly supplied to the entire area of the substrate WF that is the target to be polished.

Referring to FIG. 4B, in an embodiment, the slurry supplier 240 may be positioned with a plurality of pipes. Specifically, the slurry supplier 240 may be designed to extend through the polishing pads 210 in order to supply slurry to a plurality of areas among the areas subject to polishing of the substrate WF. For example, the slurry supplier 240 may have one pipe extending through at least a portion of the polishing pad driver 230, and the pipe may extend through a plurality of areas of the polishing pad 210 and may be positioned as a plurality of pipes. As a non-limiting example, the pipes may be positioned through the polishing pad support plate 220.

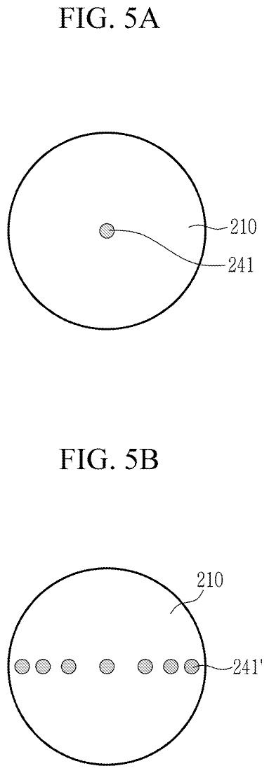

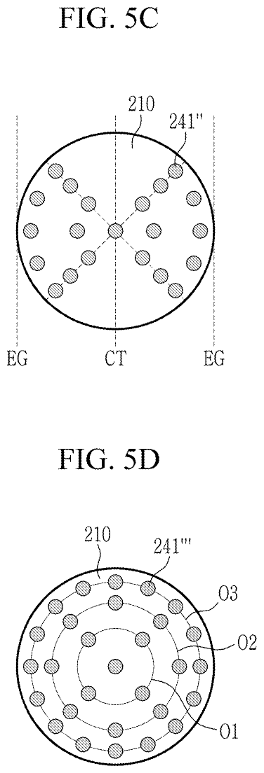

FIGS. 5A to 5D illustrate various examples of a nozzle 241 positioned on the polishing pad 210 of the present disclosure.

FIGS. 5A to 5D illustrate the nozzle 241 positioned on the polishing pad 210 and through which slurry is sprayed when the polishing pad 210 of the present disclosure is viewed from below.

Referring to FIG. 5A, the nozzle 241 may be positioned in the central portion of the polishing pad 210. If the nozzle 241 is positioned in the central portion of the polishing pad 210, as the substrate support plate 100 and the rotation member 200 rotate, as time passes, the sprayed slurry may be evenly supplied to an entire surface of the substrate WF that is the target to be polished.

Referring to FIG. 5B, a plurality of nozzles 241′ may be included. In an embodiment, the slurry supplier 240 includes the nozzles 241′ extending through the polishing pad 210, and the nozzles 241′ may be positioned on the same line. Specifically, the nozzles 241′ may be positioned along the same line at a central portion of the polishing pad 210. If the nozzles 241′ are positioned on the same line, the slurry is supplied to the substrate WF through the nozzles 241′, thereby increasing an amount of slurry supplied to the substrate WF to increase polishing efficiency. Although FIG. 5B shows that the nozzles 241′ are positioned in a row on the same line, this is a non-limiting example, and the injection nozzles 241′ may be positioned on various lines and spaced apart at various intervals.

Referring to FIG. 5C, in an embodiment, the slurry supplier 240 includes a plurality of nozzles 241″ extending the polishing pad 210, and the nozzles 241″ may be positioned such that a number thereof increases from a central portion CT to an edge EG of the polishing pad 210. Specifically, when the polishing pad 210 rotates, the number of nozzles may be adjusted such that the same amount of slurry may be supplied to the same area.

More specifically, the central portion CT of the polishing pad 210 may supply the same amount of slurry to the same area regardless of whether the polishing pad 210 is rotated, but it takes a certain amount of time until one nozzle 241″ rotates from the central portion CT to the edge EG and returns to the same position, and accordingly, slurry may not be smoothly supplied to the same area during a predetermined time. To prevent such a problem, the number of nozzles 241″ may increase from the central portion CT to the edge EG of the polishing pad 210.

FIG. 5C shows that the nozzles 241″ is positioned in a fan shape moving from the central portion CT to the edge EG of the polishing pad 210, but this is a non-limiting example, and any shape in which the number of nozzles 241″ increases as it moves from the central portion CT to the edge EG of the polishing pad 210 may be included.

Referring to FIG. 5D, in an embodiment, the slurry supplier 240 includes a plurality of nozzles 241′″ extending across the polishing pad 210, and the nozzles 241′″ may be positioned to be spaced apart at predetermined intervals along a plurality of concentric circles sharing a center of the polishing pad 210. Specifically, the nozzles 241′″ are arranged at equal intervals along the concentric circles to supply the same amount of slurry to the same area of the substrate WF in response to a rotation speed of the polishing pad 210.

In an embodiment, the concentric circles may be spaced apart at equal intervals. The slurry may be uniformly supplied to the substrate WF by spacing the concentric circles at equal intervals.

In an embodiment, the nozzles 241′″ within concentric circles O1, O2, and O3 may be spaced apart at equal intervals. In an embodiment, the intervals between the nozzles 241′″ in the concentric circles O1, O2, and O3 may be different from each other. Specifically, the intervals between the nozzles 241′″ arranged along the concentric circles O1, O2, and O3 may be narrowed from the central portion CT to the edge EG of the polishing pad 210.

The edge portion EG may require a larger number of nozzles 241′″ than the central portion CT in order to supply the same amount of slurry to the same area from the central portion CT to the edge portion EG of the polishing pad 210. Accordingly, the intervals between the nozzles 241“ ” on the same concentric circles O1, O2, and O3 may become narrower from the central portion CT to the edge portion EG of the polishing pad 210.

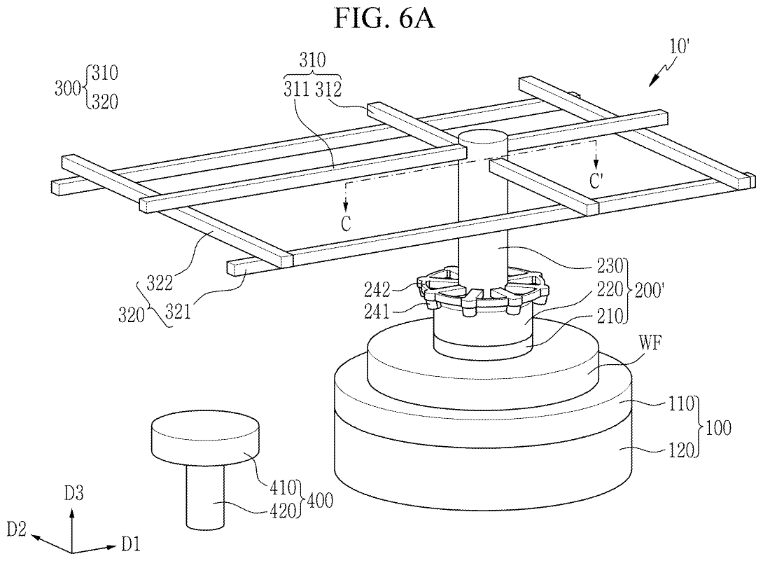

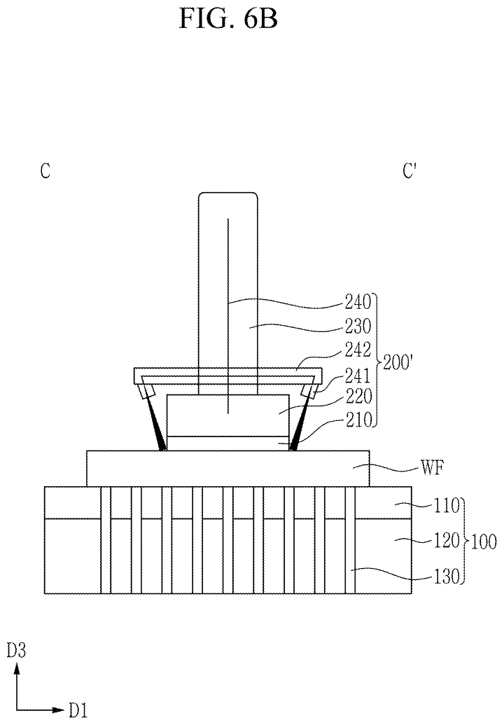

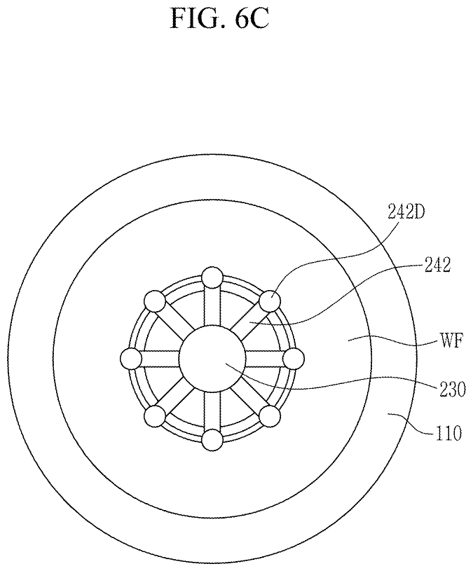

FIG. 6A illustrates a perspective view of a chemical mechanical polishing apparatus 10′ according to an embodiment of the present disclosure, FIG. 6B illustrates a cross-sectional view taken along a CC′ direction of the chemical mechanical polishing apparatus 10′ of FIG. 6A, and FIG. 6C′ illustrates a plan view of the chemical mechanical polishing apparatus 10′ of FIG. 6A.

Referring to FIG. 6A, the chemical mechanical polishing apparatus 10′ may include a substrate support plate 100 supporting the substrate WF, a rotation member 200′ positioned on the substrate support plate 100 and including a polishing pad 210 for polishing the substrate WF, and a Jig member 300 supporting and moving the rotation member 200′ . . . . As illustrated in FIG. 6B, the rotation member 200′ may include a slurry supplier 240 that is positioned on the polishing pad 210 and supplies slurry to the substrate WF. For detailed descriptions of the substrate support plate 100, the rotation member 200′, and the jig member 300, reference may be made to the above-described contents in FIGS. 1A to 1C and FIGS. 2A to 2D to the extent that they do not contradict each other.

In an embodiment, the rotation member 200′ may include a slurry supplier 240 positioned above the polishing pad 210 and including a slurry supply valve 242 positioned to surround the polishing pad 210. Specifically, the slurry supplier 240 may be positioned to extend through at least a portion of the polishing pad driver 230, and may be connected to the slurry supply valve 242 disposed on the polishing pad 210.

The slurry supply valve 242 may be positioned on the polishing pad 210, specifically on the polishing pad support plate 220, and may be positioned to surround a lower end of the polishing pad driver 230, so as to supply slurry while minimizing interference when the polishing pad 210 and the polishing pad support plate 220 rotate.

In an embodiment, the slurry supply valve 242 may supply slurry to the substrate WF at the same position without rotation when the polishing pad driver 230 rotates the polishing pad 210. The slurry supply valve 242 may not rotate separately and may be positioned at a fixed position to supply slurry to the substrate WF, thereby supplying the slurry to a polishing portion more precisely and increasing polishing efficiency of the substrate WF.

In an embodiment, the slurry supply valve 242 may include at least one nozzle 241 that directly supplies slurry onto the substrate WF. Specifically, the slurry supply valve 242 may include a plurality of nozzles 241. The slurry supply valve 242 may include the nozzles 241 to spray the slurry efficiently according to a position of an area of the substrate WF that needs to be polished.

In an embodiment, the nozzles 241 may be symmetrically positioned on the same line. Specifically, the nozzles 241 may be positioned symmetrically with respect to a central portion of the polishing pad driver 230 within the rotation member 200′.

For example, in FIG. 6C, eight nozzles 241 are illustrated to be symmetrically positioned, but this is a non-limiting example, and a number of nozzles 241 in FIG. 6C does not limit the present disclosure, and may include 2, 4, 12, or more nozzles 241.

In an embodiment, the nozzles 241 may be connected to the slurry supply valve 242, and whether or not the slurry is introduced or an amount thereof may be controlled by a valve opening and closing port 242D. The valve opening and closing port 242D may efficiently utilize the slurry during polishing by controlling whether or not the amount of slurry sprayed into the nozzles 241 is inputted.

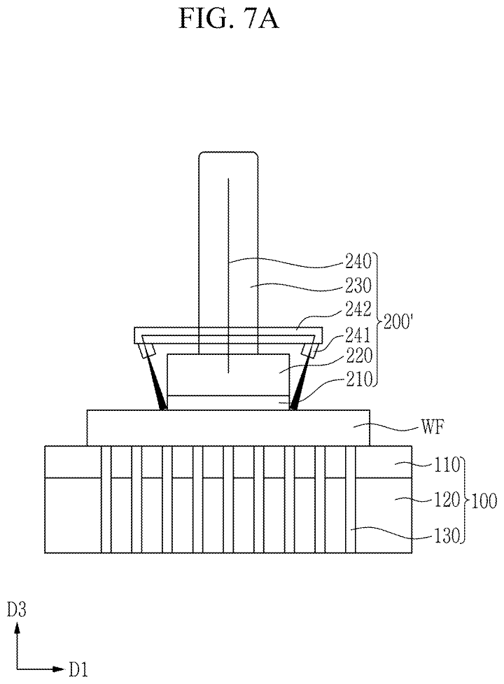

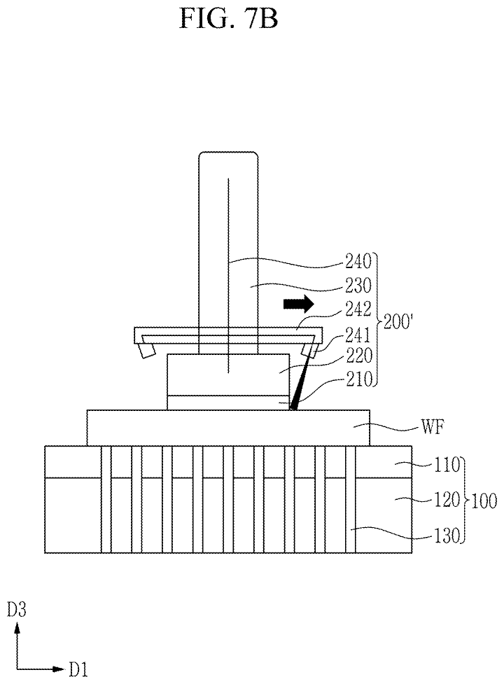

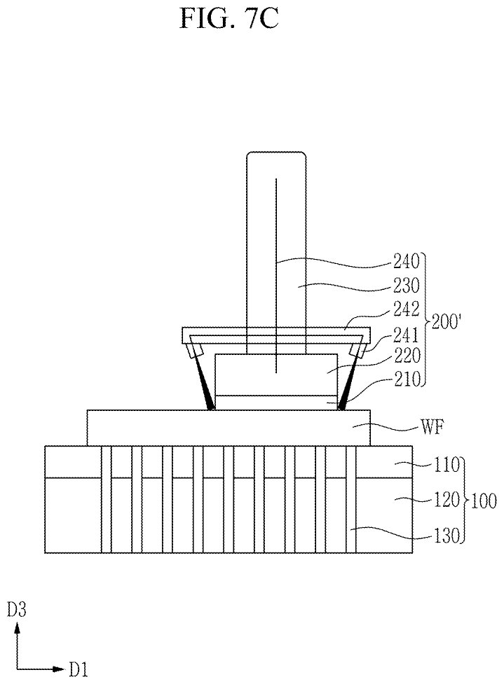

FIGS. 7A to 7C schematically illustrate a method of driving a chemical mechanical polishing apparatus 10′ according to an embodiment of the present disclosure.

Referring to FIG. 7A, the chemical mechanical polishing apparatus 10′ may perform polishing by moving the rotation member 200′ to the substrate WF that is a target to be polished by the jig member 300. In this case, in order to increase polishing efficiency, the slurry supplier 240 within the rotation member 200′ may directly supply the slurry onto the substrate WF through the nozzles 241.

Referring to FIG. 7B, in an embodiment, for the nozzles 241, at least one nozzle 241 positioned in a direction opposite to a moving direction of the polishing pad 210 is closed, an at least one nozzle 241 positioned in a direction in which the polishing pad 210 moves may be open. For example, when the polishing pad 210 moves in a direction D1 and polishes the substrate WF, the nozzles 241 positioned in the direction D1 may be opened to supply the slurry for polishing the substrate WF. In this case, the nozzles 241 positioned in a direction-D1 that is opposite to the direction D1 may be closed to efficiently control the amount of slurry supplied.

Referring to FIG. 7C, in an embodiment, the rotation member 200 that has reached the area of the substrate WF that is the target to be polished may increase polishing efficiency by additionally supplying slurry from the nozzles 241 to polish the substrate WF.

The present disclosure may be embodied in many different forms, and should not be construed as being limited to the above implementation and/or embodiments. In addition, it will be understood by those skilled in the art that various changes in form and details may be made thereto without departing from the technical spirit and essential features of the present disclosure. Therefore, it is to be understood that the above implementation and/or embodiments are for illustrative purposes only, and the scope of the present disclosure is not limited thereto.

### DESCRIPTION OF SYMBOLS

10, 10′: chemical mechanical polishing apparatus
100: substrate support plate
110: first support plate
120: second support plate
130: pressure provider
200: rotation member
210: polishing pad
220: polishing pad support plate
230: polishing pad driver
240: slurry supplier
241: nozzle
242: slurry supply valve
300: jig member
310, 320: first and second jig member
311, 312: first and second movement jigs
321, 322: first and second support jigs

What is claimed is:

1. A chemical mechanical polishing apparatus comprising:
a substrate support plate configured to support a substrate;
a rotation member positioned on the substrate support plate;
a polishing pad connected to the rotation member and disposed between the rotation member and the substrate support plate; and
a jig member positioned above the substrate support plate and movably connected to the rotation member.

2. The chemical mechanical polishing apparatus of claim 1, wherein
the jig member guides the rotation member to move in a direction parallel to a surface of the substrate support plate.

3. The chemical mechanical polishing apparatus of claim 2, wherein
the jig member includes a first jig member that supports and moves the rotation member and a second jig member that supports the first jig member.

4. The chemical mechanical polishing apparatus of claim 3, wherein
the rotation member is connected to the first jig member to be movable along the first jig member, and
the first jig member includes a first movement jig extending in a first direction and a second movement jig extending in a second direction intersecting the first direction.

5. The chemical mechanical polishing apparatus of claim 4, wherein
the second jig member includes a first support jig extending in the first direction and supporting the second movement jig and a second support jig extending in the second direction and supporting the first movement jig.

6. The chemical mechanical polishing apparatus of claim 1, wherein
a diameter of the polishing pad is smaller than a diameter of the substrate.

7. The chemical mechanical polishing apparatus of claim 1, wherein
the substrate support plate moves in a direction that is perpendicular to a surface of substrate.

8. The chemical mechanical polishing apparatus of claim 1, further comprising:
a conditioner spaced apart from the substrate support plate and configured to include a polisher for polishing the polishing pad,
wherein a diameter of the polisher is larger than the diameter of the polishing pad.

9. The chemical mechanical polishing apparatus of claim 1, wherein
the rotation member includes a slurry supplier that directly supplies slurry to the substrate.

10. The chemical mechanical polishing apparatus of claim 9, wherein
the slurry supplier is included in the rotation member, and is positioned to extend through the polishing pad.

11. The chemical mechanical polishing apparatus of claim 9, wherein
the slurry supplier includes a nozzle positioned to extend through a central portion of the polishing pad.

12. The chemical mechanical polishing apparatus of claim 9, wherein
the slurry supplier includes a plurality of nozzles extending through the polishing pad, and
the nozzles are positioned on the same line.

13. The chemical mechanical polishing apparatus of claim 9, wherein
the slurry supplier includes a plurality of nozzles extending through the polishing pad, and
the number of nozzles included in a central portion of the polishing pad is less than the number of nozzles included in an edge portion of the polishing pad.

14. The chemical mechanical polishing apparatus of claim 9, wherein
the slurry supplier includes a plurality of nozzles extending through the polishing pad, and
the nozzles are arranged to be spaced apart at predetermined intervals along a plurality of concentric circles.

15. The chemical mechanical polishing apparatus of claim 1, wherein
the substrate support plate includes a pressure provider configured to fix the substrate to the substrate support plate.

16. A chemical mechanical polishing apparatus comprising:
a substrate support plate configured to support a substrate;
a rotation member positioned on the substrate support plate;
a polishing pad connected to the rotation member and disposed between the rotation member and the substrate support plate; and
a jig member positioned above the substrate support plate and movably connected to the rotation member,
wherein the rotation member includes a slurry supplier positioned on the polishing pad and configured to include a slurry supply valve positioned to surround the polishing pad, and
the slurry supply valve includes at least one nozzle for directly supplying slurry onto the substrate.

17. The chemical mechanical polishing apparatus of claim 16, wherein
the slurry supply valve includes a plurality of nozzles arranged around the rotation member.

18. The chemical mechanical polishing apparatus of claim 17, wherein
the nozzles are symmetrically positioned with respect to a central portion of a polishing driver within the rotation member.

19. The chemical mechanical polishing apparatus of claim 18, wherein
the slurry supply valve is configured to open a nozzle positioned in a moving direction of the polishing pad, and
the slurry supply valve is configured to close a nozzle positioned in a direction opposite to the moving direction of the polishing pad.

20. A chemical mechanical polishing apparatus comprising:
a substrate support plate configured to fix a substrate by providing pressure to the substrate;
a rotation member including a polishing pad support plate, a polishing pad attached to the polishing pad support plate, a polishing pad driver configured to rotate the polishing pad and the polishing pad support plate, and a slurry supplier positioned to extend through the polishing pad; and
a jig member including
a first jig member connected to the rotation member, and
a second jig member in contact with the first jig member.
